(19) United States
(12) Patent Application Publication
(10) Pub. No.: US 2023/0063973 A1
(43) Pub. Date: Mar. 2, 2023

(54) FET WITH REDUCED PARASITIC CAPACITANCE

(71) Applicant: INTERNATIONAL BUSINESS MACHINES CORPORATION, Armonk, NY (US)

(72) Inventors: Ruilong Xie, Niskayuna, NY (US); Chen Zhang, Guilderland, NY (US); Brent Anderson, Jericho, VT (US); Robert Robison, Rexford, NY (US); Ardasheir Rahman, Schenectady, NY (US); Hemanth Jagannathan, Niskayuna, NY (US)

(21) Appl. No.: 17/446,626

(22) Filed: Sep. 1, 2021

(51) Int. Cl. H01L 27/06; H01L 29/78; H01L 21/8234

(52) U.S. Cl. CPC H01L 27/0629; H01L 29/78; H01L 21/8234

(57) ABSTRACT

An apparatus comprising a plurality of FET columns located on a substrate. A source/drain layer located around the base of the plurality of FET columns. A dielectric layer located around the source/drain layer, wherein a portion of the dielectric layer that is sandwiched between a first portion of the source/drain layer and a second portion of the source/drain layer. A gate layer, wherein the gate layer has a first portion located on top of the source/drain layer, and wherein the gate layer has a second portion located on top of the portion of the dielectric layer that is sandwiched between a first portion of the source/drain layer and a second portion of the source/drain layer.

### BACKGROUND

The present invention generally relates to the field of FET devices, and more particularly to reducing the parasitic capacitance between a bottom source/drain epi and a gate metal.

FET device come in multiple designs but all of them have a source/drain epi that is formed around the FET formation. A gate is formed on top of the source/drain epi and a natural capacitor is formed between the gate metal and the source/drain epi. This naturally forming capacitor is considered a parasitic capacitor since it negatively affects the performance of the FET device.

### BRIEF SUMMARY

Additional aspects and/or advantages will be set forth in part in the description which follows and, in part, will be apparent from the description, or may be learned by practice of the invention.

An apparatus comprising a plurality of FET columns located on a substrate. A source/drain layer located around the base of the plurality of FET columns. A dielectric layer located around the source/drain layer, wherein a portion of the dielectric layer that is sandwiched between a first portion of the source/drain layer and a second portion of the source/drain layer. A gate layer, wherein the gate layer has a first portion located on top of the source/drain layer, and wherein the gate layer has a second portion located on top of the portion of the dielectric layer that is sandwiched between a first portion of the source/drain layer and a second portion of the source/drain layer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1A illustrates a top-down view of a FET device, in accordance with an embodiment of the present invention.

FIG. 1B illustrates cross section B of the FET device, in accordance with the embodiment of the present invention.

FIG. 1C illustrates cross section C of the FET device, in accordance with the embodiment of the present invention.

FIG. 2A illustrates a top-down view of a FET device after formation of the source/drain epi, in accordance with an embodiment of the present invention.

FIG. 2B illustrates cross section B of the FET device after formation of the source/drain epi, in accordance with the embodiment of the present invention.

FIG. 2C illustrates cross section C of the FET device after formation of the source/drain epi, in accordance with the embodiment of the present invention.

FIG. 3A illustrates a top-down view of a FET device after formation of the liner, in accordance with an embodiment of the present invention.

FIG. 3B illustrates cross section B of the FET device after formation of the liner, in accordance with the embodiment of the present invention.

FIG. 3C illustrates cross section C of the FET device after formation of the liner, in accordance with the embodiment of the present invention.

FIG. 4A illustrates a top-down view of a FET device after formation of the lithography layer, in accordance with an embodiment of the present invention.

FIG. 4B illustrates cross section B of the FET device after formation of the lithography layer, in accordance with the embodiment of the present invention.

FIG. 4C illustrates cross section C of the FET device after formation of the lithography layer, in accordance with the embodiment of the present invention.

FIG. 5A illustrates a top-down view of a FET device after trimming of the source/drain epi, in accordance with an embodiment of the present invention.

FIG. 5B illustrates cross section B of the FET device after trimming of the source/drain epi, in accordance with the embodiment of the present invention.

FIG. 5C illustrates cross section C of the FET device after trimming of the source/drain epi, in accordance with the embodiment of the present invention.

FIG. 6A illustrates a top-down view of a FET device after formation of a dielectric layer, in accordance with an embodiment of the present invention.

FIG. 6B illustrates cross section B of the FET device after formation of a dielectric layer, in accordance with the embodiment of the present invention.

FIG. 6C illustrates cross section C of the FET device after formation of a dielectric layer, in accordance with the embodiment of the present invention.

FIG. 7A illustrates a top-down view of a FET device after formation of the gate, in accordance with an embodiment of the present invention.

FIG. 7B illustrates cross section B of the FET device after formation of the gate, in accordance with the embodiment of the present invention.

FIG. 7C illustrates cross section C of the FET device after formation of the gate, in accordance with the embodiment of the present invention.

FIGS. 8A, 8B, and 8C illustrates a top-down view of different FET devices after trimming of the source/drain epi, in accordance with an embodiment of the present invention.

FIGS. 9A, 9B, and 9C illustrates a top-down view of a group of FET devices after trimming of the source/drain epi, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various process used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others.

Removal/etching is any process that removes material from the wafer. Examples include etching process (either wet or dry), reactive ion etching (ME), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, wherein like reference numerals refer to like elements throughout. A natural capacitor is formed between a source/drain epi and a gate that is located above/below the source/drain epi. The natural capacitor is considered a parasitic capacitor since it negatively affects the performance of the FET device. The source/drain epi is usually formed in a wide area to enclose a bottom portion of the FET columns. Not all the source/drain epi material is need to from the necessary connection to the FET columns. The source/drain epi is trimmed to removes some of the epi material to reduce the overlapping area of the source/drain epi and the gate. The overlapping area between the source/drain epi and the gate is reduced causing a reduction in the size of the parasitic capacitor and causes the capacitance to be reduced.

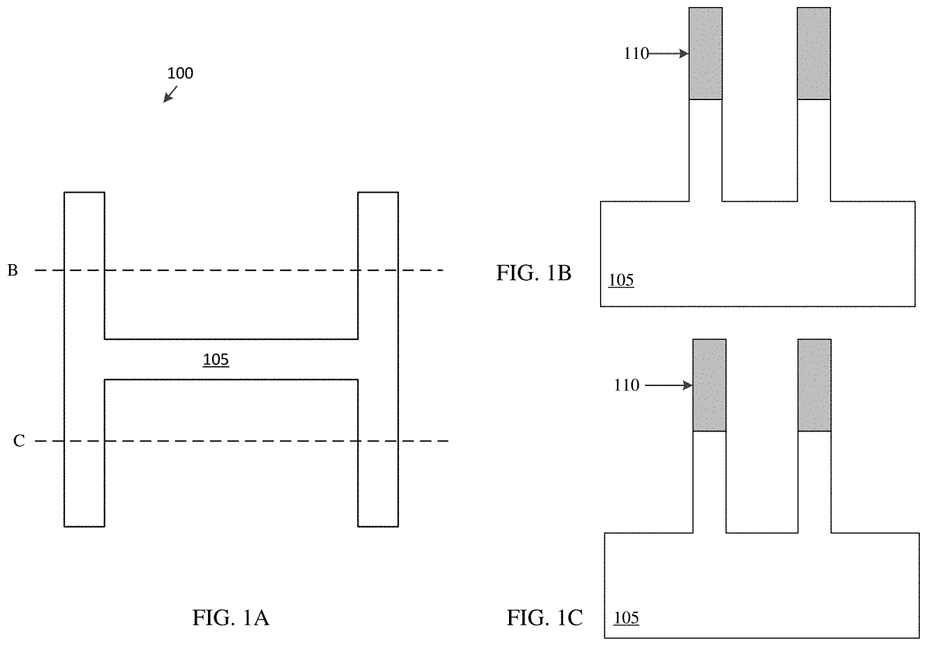

FIG. 1A illustrates a top-down view of a FET device 100, in accordance with an embodiment of the present invention. FIG. 1B illustrates cross section B of the FET device 100, in accordance with the embodiment of the present invention. FIG. 1C illustrates cross section C of the FET device 100, in accordance with the embodiment of the present invention.

FIG. 1A illustrates a top-down view of a H shaped FET device 100. The H shaped FET device 100 includes a substrate 105 and a hard mask 110. The substrate 105 can be, for example, a material including, but not necessarily limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or entire semiconductor substrate 105 may also comprise an amorphous, polycrystalline, or monocrystalline. The semiconductor substrate 105 may be doped, undoped or contain doped regions and undoped regions therein. Substrate 105 includes columns that extend vertically, where in this example the extending columns form an H shape when viewed from a top-down position. A hard mask 110 is formed on top of the columns of the substrate 105 as illustrated in FIGS. 1B and 1C.

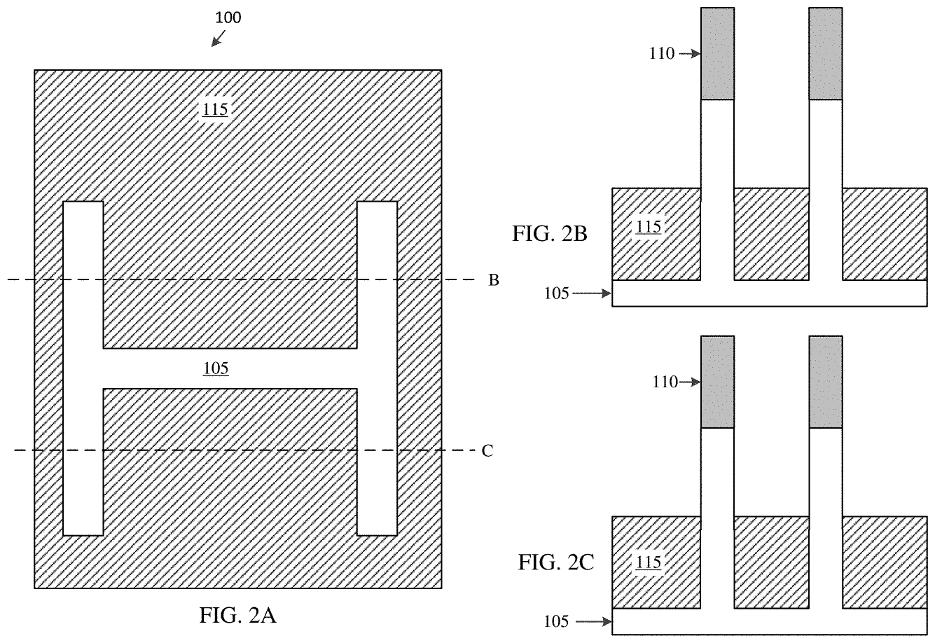

FIG. 2A illustrates a top-down view of a FET device 100 after formation of the source/drain epi 115, in accordance with an embodiment of the present invention. FIG. 2B illustrates cross section B of the FET device 100 after formation of the source/drain epi 115, in accordance with the embodiment of the present invention. FIG. 2C illustrates cross section C of the FET device 100 after formation of the source/drain epi 115, in accordance with the embodiment of the present invention.

The substrate 105 is etched to create trenches around the legs/base of the FET columns/fins that make the H shaped FET device 100. A source/drain epi 115 is formed in the trenches to enclose a bottom portion of the columns of the substrate 105 that comprise the H shaped FET device 100. The source/drain epi 115 can be for example, a n-type epi, or a p-type epi. For n-type epi, an n-type dopant selected from a group of phosphorus (P), arsenic (As) and/or antimony (Sb) can be used. For p-type epi, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

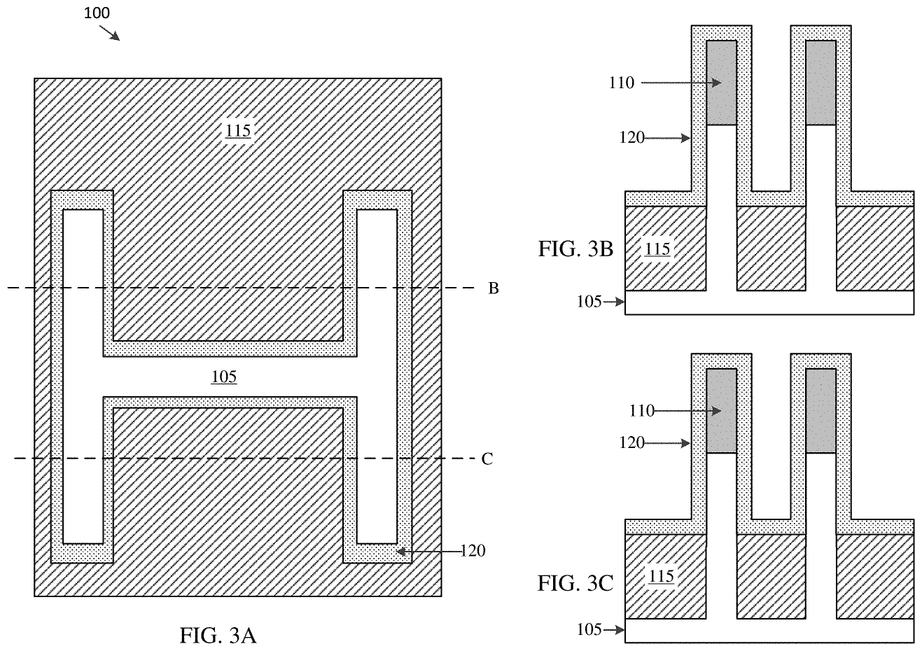

FIG. 3A illustrates a top-down view of a FET device 100 after formation of the liner 120, in accordance with an embodiment of the present invention. FIG. 3B illustrates cross section B of the FET device 100 after formation of the liner 120, in accordance with the embodiment of the present invention. FIG. 3C illustrates cross section C of the FET device 100 after formation of the liner 120, in accordance with the embodiment of the present invention. A portion of the substrate 105 that forms the FET extends above the source/drain epi 115. A liner 120 is formed on the top surface of the source/drain epi 115 and along the side surfaces of the substrate 105 and hard mask 110 that extends above the source/drain epi 115.

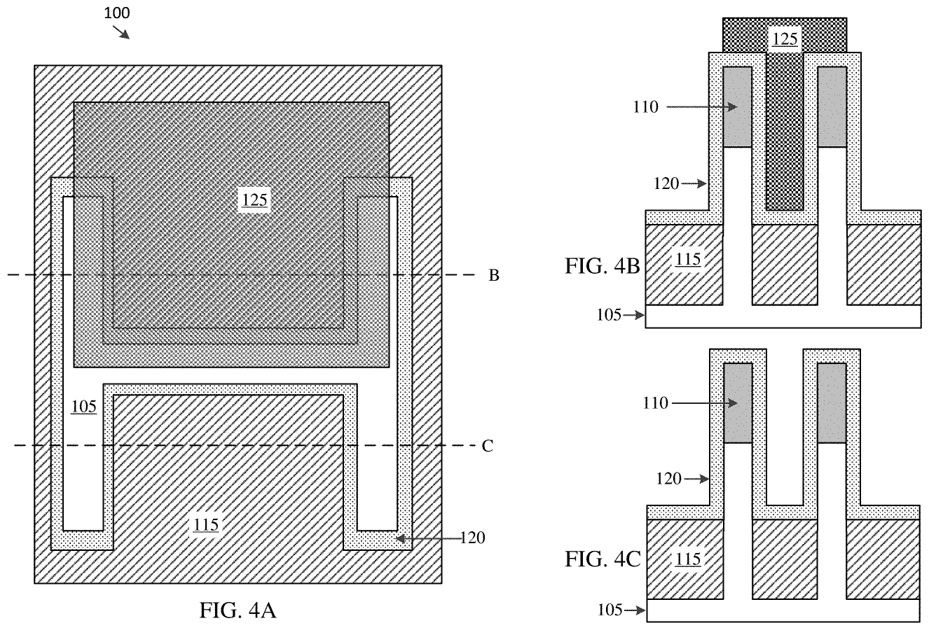

FIG. 4A illustrates a top-down view of a FET device 100 after formation of the lithography layer 125, in accordance with an embodiment of the present invention. FIG. 4B illustrates cross section B of the FET device 100 after formation of the lithography layer 125, in accordance with the embodiment of the present invention. FIG. 4C illustrates cross section C of the FET device 100 after formation of the lithography layer 125, in accordance with the embodiment of the present invention. A lithography layer 125 is formed on top of the liner 120. The lithography layer 125 does not cover the entire liner 120 (i.e., the entire area of the source/drain epi 115). The lithography layer 125 covers only a portion of the liner 120 to protect a portion of the underlying source/drain epi 115. The source/drain epi 115 is protected by the lithography layer 125 from being removed during the trimming stage.

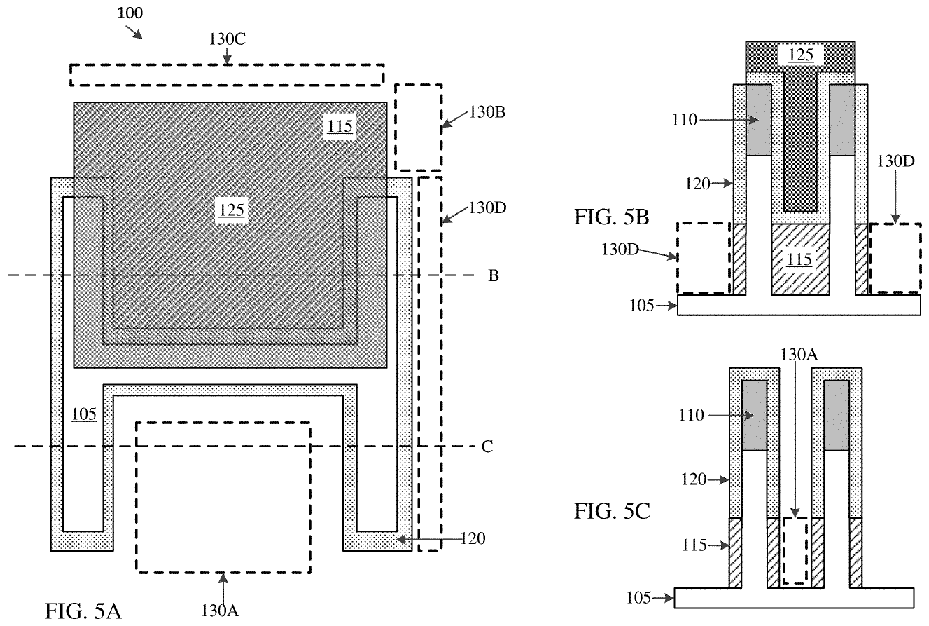

FIG. 5A illustrates a top-down view of a FET device 100 after trimming of the source/drain epi 115, in accordance with an embodiment of the present invention. FIG. 5B illustrates cross section B of the FET device 100 after trimming of the source/drain epi 115, in accordance with the embodiment of the present invention. FIG. 5C illustrates cross section C of the FET device 100 after trimming of the source/drain epi 115, in accordance with the embodiment of the present invention. The source/drain epi 115 is trimmed by an etching process, such as, reactive ion etching (ME). The lithography layer 125 protects a portion of the source/drain epi 115 from being etched. Also, the portion of the liner 120 that is located adjacent to the FET columns protects the underlying source/drain epi 115 from being trimmed. Dashed boxes 130A, 130B, 130C, 130D illustrate example locations where the source/drain epi 115 was removed. A portion of the source/drain epi 115 that is remaining is located below the lithography layer 125. FIG. 5B illustrates the remaining source/drain epi 115 that is located below the lithography layer 125. FIG. 5C illustrates that the source drain epi 115 is no longer present between sections of the FET columns. FIG. 5C also illustrates that a portion of the source/drain epi 115 is located below the remaining sections of the liner 120. The trimming of the source/drain epi 115 reduces the amount of overlap between the source/drain epi 115 and the gate 145 (which will be described below). Trimming the source/drain epi 115 reduces the amount of overlap between the source/drain epi 115 and the gate 145, which causes the capacitance of the parasitic capacitor to be reduced.

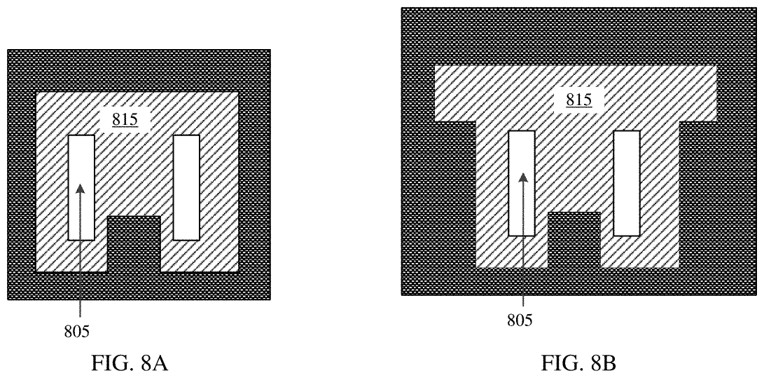

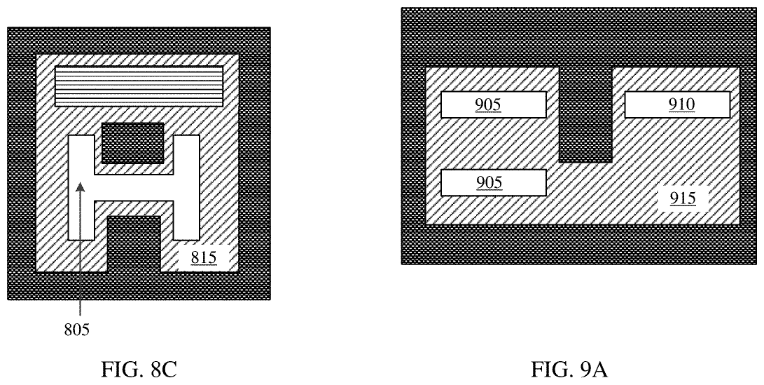

The trimming of the source/drain epi 115 can be controlled by the placement of the lithography layer 125, thus allowing flexibility in the trimming process. For example, FIGS. 8A, 8B, and 8C each illustrate a top-down view of different examples for trimming the source/drain epi 815. FIG. 8A illustrates two parallel FET columns 805 where the bottom portion of the source/drain epi 815 that is located between the FET columns 805 is trimmed. FIG. 8B illustrates a design that is similar to what is shown in FIG. 8A, but where the source/drain epi 815 that is located outside of the FET columns 805 is further trimmed. FIG. 8C illustrates an H shaped FET column 805 where different sections of the source/drain epi 815 is trimmed. A first portion of the source/drain epi 815 that is located between the bottom portion of the H shaped FET column 805 is trimmed. Also, a second portion of the source/drain epi 815 that is located between the top portion of the H shaped FET column 805 is trimmed. FIGS. 8A, 8B, and 8C are meant to be examples as to illustrate different ways that the source/drain epi 115/815 can be trimmed based on the design for the FET device. The source/drain epi 115/815 can be trimmed in many different configurations to reduce the amount of unnecessary epi material.

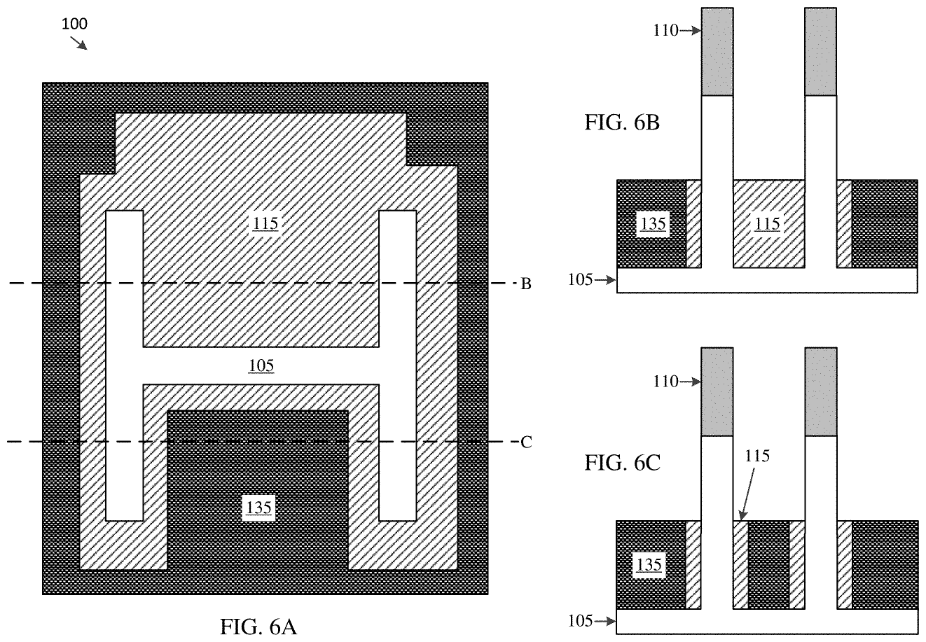

FIG. 6A illustrates a top-down view of a FET device 100 after formation of a dielectric layer 135, in accordance with an embodiment of the present invention. FIG. 6B illustrates cross section B of the FET device 100 after formation of a dielectric layer 135, in accordance with the embodiment of the present invention. FIG. 6C illustrates cross section C of the FET device 100 after formation of a dielectric layer 135, in accordance with the embodiment of the present invention. A dielectric layer 135 is formed on top of the substrate 105 adjacent to the source/drain epi 115. As FIG. 6B illustrates the dielectric layer 135 is not located between the columns of the FET device since the source/drain epi 115 remains at this location. FIG. 6C illustrates that the dielectric layer 135 is located between the FET columns since the source/drain epi 115 was trimmed at this location. As illustrated by FIG. 6A and FIG. 6C illustrate a bottom section of the H shaped FET device 100, where the dielectric layer 135 is sandwiched between sections of the source/drain epi 115 located on the legs/base of FET columns. FIGS. 6A and 6B illustrate that the source/drain epi 115 is continuous between the top portion of the FET columns.

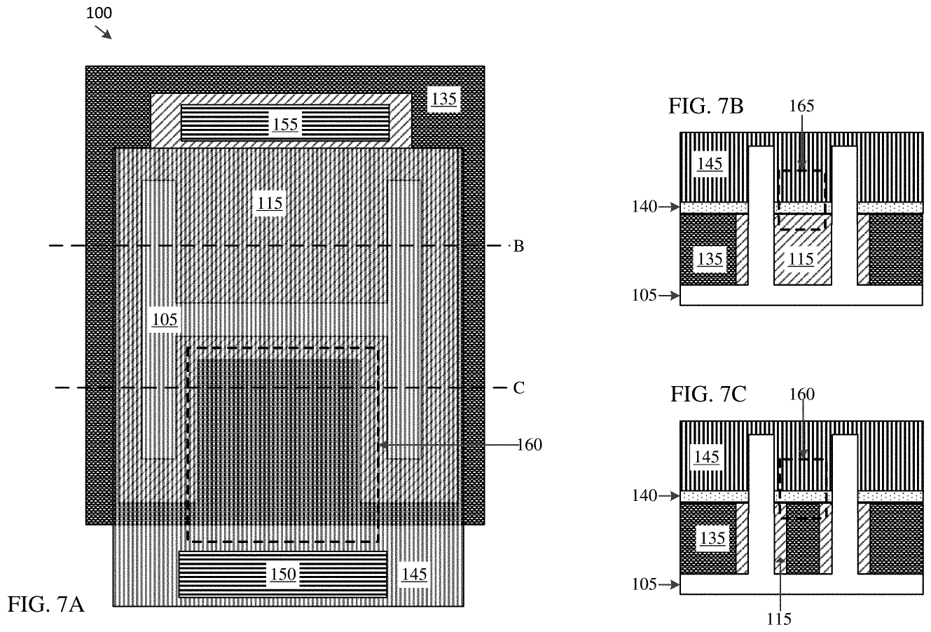

FIG. 7A illustrates a top-down view of a FET device 100 after formation of the gate 145, in accordance with an embodiment of the present invention. FIG. 7B illustrates cross section B of the FET device 100 after formation of the gate 145, in accordance with the embodiment of the present invention. FIG. 7C illustrates cross section C of the FET device 100 after formation of the gate 145, in accordance with the embodiment of the present invention. A spacer 140 is formed on top of the dielectric layer 135 and on top of the source/drain epi 115. A gate 145 is formed on top of the spacer 140, such that, the space 140 is directly beneath the gate 145. A first electrical contact 150 is in contact with the gate 145 and a second electrical contact 155 is in contact with the source/drain epi 115. Dashed box 160 as seen in FIGS. 7A and 7C illustrates that the gate 145 is located above the dielectric layer 135 between the columns for the FET device 100. Since the gate 145 is located above the dielectric layer 135 at dashed box 160, then the parasitic capacitor is not formed at this location. As seen by FIG. 7B, dashed box 165 illustrates that gate 145 is formed above the source/drain epi 115 at cross section B of the FET device 100. At this location, a natural capacitor is formed between the gate 145 and the source/drain epi 115. Trimming of the source/drain epi 115 causes a reduction of the capacitance of the natural (parasitic) capacitor by reducing the size of the capacitor.

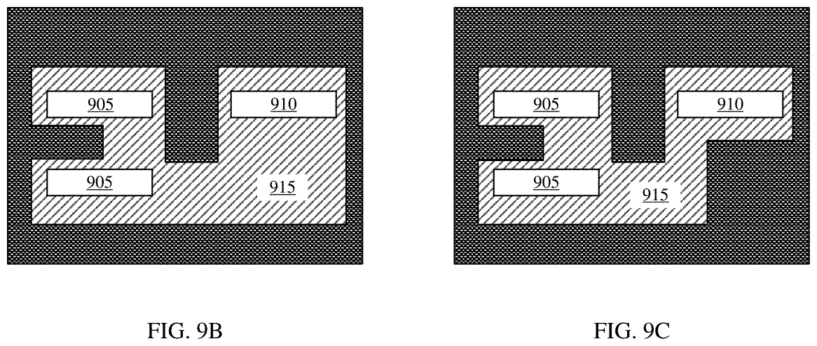

FIGS. 9A, 9B, and 9C illustrates a top-down view of a group of FET devices after trimming of the source/drain epi, in accordance with an embodiment of the present invention. FIGS. 9A, 9B, and 9C illustrates multiple FET devices using a common source/drain epi 915. The FET devices includes an NFET device 905 and a PFET device 910. The source/drain epi 915 can be trimmed between the devices as illustrated by FIG. 9A. The source/drain epi 915 can be trimmed between devices and trimmed between the columns of the NFET device 905, as illustrated by FIG. 9B. FIG. 9C illustrates that the source/drain epi 915 can be trimmed at other locations to reduce the amount of source/drain epi material to overlap with a gate. FIGS. 8A, 8B, 8C, 9A, 9B, and 9C are meant to illustrate that the source/drain epi 115/815/915 can be trimmed in any amount, in any location to reduces the amount of overlap between the source/drain epi 115/815/915 and a gate. This prevents the formation of the parasitic capacitor at the locations where the source/drain epi material was removed.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An apparatus comprising:
a plurality of FET columns located on a substrate;
a source/drain layer located around the base of the plurality of FET columns;
a dielectric layer located around the source/drain layer, wherein a portion of the dielectric layer that is sandwiched between a first portion of the source/drain layer and a second portion of the source/drain layer; and
a gate layer, wherein the gate layer has a first portion located on top of the source/drain layer, and wherein the gate layer has a second portion located on top of the portion of the dielectric layer that is sandwiched between the first portion of the source/drain layer and the second portion of the source/drain layer.

2. The apparatus of claim 1, wherein the plurality of FET columns forms an H shape.

3. The apparatus of claim 2, wherein the first portion of the source/drain layer is located adjacent to a first FET column of the plurality FET columns that makes one of the legs for the H-shape.

4. The apparatus of claim 3, wherein the second portion of the source/drain layer is located adjacent to a second FET column of the plurality FET columns that makes one of the legs for the H-shape.

5. The apparatus of claim 2, wherein the portion of the dielectric layer that is sandwiched between the first portion of the source/drain layer and the second portion of the source/drain layer is located at the bottom section of the H-shape for the plurality of FET columns.

6. The apparatus of claim 5, wherein the source/drain layer is continuous between the portions of the plurality of FET columns that makes the upper portion of the H-shaped.

7. The apparatus of claim 2, wherein the gate layer is located on top of the source/drain layer between the portions of the plurality of FET columns that makes the upper portion of the H-shaped.

8. The apparatus of claim 7, wherein the gate layer is located on top of the dielectric layer between the portions of the plurality of FET columns that makes the lower portion of the H-shaped.

9. The apparatus of claim 1, further comprising:
a spacer located directly underneath the gate layer, wherein the spacer is located directly on top of the dielectric layer or directly on top of the source/drain layer.

10. An apparatus comprising:
a FET device located on a substrate;
a PFET device located on the substrate;
a source/drain layer located on the substrate around the base of the FET device and the PFET device; and
a dielectric layer located around the source/drain layer, wherein a first portion of the dielectric layer that is sandwiched between a first portion of the source/drain layer located around the FET device and a second portion of the source/drain layer located around the PFET device, and wherein the first portion of the source/drain layer is continuous between the FET device and the PFET device.

11. The apparatus of claim 10, wherein the FET device is comprised of a plurality of FET columns.

12. The apparatus of claim 11, wherein a second portion of the dielectric layer that is sandwiched between a third portion of the source/drain layer located around a first column of the FET device and a fourth portion of the source/drain layer located around a second column of the FET device.

13. A method comprising:
forming a plurality of FET columns on a substrate;
forming a source/drain layer around the bottom of the FET columns;
trimming the source/drain layer to remove portions of the source/drain layer located around the FET columns;
forming a dielectric layer located on the substrate, wherein a portion of the dielectric layer is sandwiched between a first portion of the source/drain layer and a second portion of the source/drain layer.

14. The method of claim 13, further comprising:
forming a spacer layer, wherein a portion of the spacer layer is located on top of the source/drain layer and a portion of the spacer layer is located on top of the dielectric layer.

15. The method of claim 14, further comprising:
forming a gate layer on top of the spacer layer, wherein the gate layer has a first portion located on top of the source/drain layer, and wherein the gate layer has a second portion located on top of the portion of the dielectric layer that is sandwiched between a first portion of the source/drain layer and a second portion of the source/drain layer.

16. The method of claim 15, wherein the plurality of FET columns forms an H shape.

17. The method of claim 16, wherein the trimming of the source/drain layer removes a section of the source drain layer located between the bottom section of the H-shape for the plurality of FET columns.

18. The method of claim 17, wherein the first portion of the source/drain layer remains directly adjacent to one of the FET columns that comprises the bottom section of the H-shape, and wherein the second portion of the source/drain layer remains directly adjacent to one of the FET columns that comprises the bottom section of the H-shape.

19. The method of claim 18, wherein the source/drain layer is continuous between the portions of the plurality of FET columns that makes the upper portion of the H-shaped.

20. The method of claim 19, wherein the gate layer is located on top of the source/drain layer between the portions of the plurality of FET columns that makes the upper portion of the H-shaped.
